(19) United States
(12) Patent Application Publication
(10) Pub. No.: US 2023/0091229 A1
(43) Pub. Date: Mar. 23, 2023

(54) BOTTOM JUNCTION AND CONTACT AREA STRUCTURES FOR VERTICAL TRANSPORT FIELD-EFFECT TRANSISTORS

(71) Applicant: International Business Machines Corporation, Armonk, NY (US)

(72) Inventors: Tao Li, Slingerlands, NY (US); Ruilong Xie, Niskayuna, NY (US); Yann Mignot, Slingerlands, NY (US); Tsung-Sheng Kang, Ballston Lake, NY (US); Alexander Reznicek, Troy, NY (US)

(21) Appl. No.: 17/479,794

(22) Filed: Sep. 20, 2021

(51) Int. Cl. H01L 29/78; H01L 29/08; H01L 29/66

(52) U.S. Cl. CPC H01L 29/7856; H01L 29/0847; H01L 29/66795

(57) ABSTRACT

A semiconductor structure comprises at least one vertical fin, an epitaxial layer adjacent a bottom portion of the at least one vertical fin, wherein the epitaxial layer comprises a plurality of different heights, and a contact structure disposed on the epitaxial layer. The contact structure is disposed on respective surfaces of the epitaxial layer at the plurality of different heights. The epitaxial layer comprises a bottom source/drain region of at least one vertical transport field-effect transistor.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming bottom junction and contact area structures for vertical transport field-effect transistor (VTFET) structures.

In one embodiment, a semiconductor structure comprises at least one vertical fin, an epitaxial layer adjacent a bottom portion of the at least one vertical fin, wherein the epitaxial layer comprises a plurality of different heights, and a contact structure disposed on the epitaxial layer. The contact structure is disposed on respective surfaces of the epitaxial layer at the plurality of different heights. The epitaxial layer comprises a bottom source/drain region of at least one vertical transport field-effect transistor.

In another embodiment, a vertical transport field-effect transistor structure comprises at least one vertical channel region, and a bottom source/drain region adjacent a bottom portion of the at least one vertical channel region, wherein the bottom source/drain region comprises a plurality of different heights. A top source/drain region is disposed on a top portion of the at least one vertical channel region, and a contact structure is disposed on the bottom source/drain region. The contact structure is disposed on respective surfaces of the bottom source/drain region at the plurality of different heights.

In another embodiment, a method of forming a semiconductor structure comprises forming a mask on a first portion of a semiconductor substrate, wherein the first portion corresponds to a transistor region, and removing part of a second portion of the semiconductor substrate left exposed by the mask, wherein the second portion corresponds to a dummy region. In the method, a sacrificial semiconductor layer is grown in the dummy region in place of the removed part of the second portion. At least one vertical fin is formed in the transistor region, and an epitaxial layer is formed adjacent a bottom portion of the at least one vertical fin. The sacrificial semiconductor layer is selectively removed with respect to the epitaxial layer.

### BRIEF DESCRIPTION OF THE DRAWINGS

FIG. 1 shows a top-down view of a plurality of fins and a plurality of cut fin regions of a vertical transport field-effect transistor structure, according to an embodiment of the invention.

FIG. 2A shows a top-down view of formation of hardmasks covering n-type and p-type field-effect-transistor regions and exposing dummy fin regions, according to an embodiment of the invention.

FIG. 2B is a cross-sectional view taken along the line Y in FIG. 2A and illustrating a hardmask configuration, according to an embodiment of the invention.

FIG. 2C is a cross-sectional view taken along the line X1 in FIG. 2A and illustrating a hardmask configuration, according to an embodiment of the invention.

FIG. 3 is a cross-sectional view taken along the line Y in FIG. 2A and illustrating removal of portions of a substrate and growth of a semiconductor layer in place of the removed portions, according to an embodiment of the invention.

FIG. 4A shows a top-down view of formation of hardmasks for fin patterning, according to an embodiment of the invention.

FIG. 4B is a cross-sectional view taken along the line X1 in FIG. 4A and illustrating fin patterning in a p-type field-effect-transistor region, according to an embodiment of the invention.

FIG. 4C is a cross-sectional view taken along the line X3 in FIG. 4A and illustrating fin patterning in a dummy fin region, according to an embodiment of the invention.

FIG. 4D is a cross-sectional view taken along the line Y in FIG. 4A and illustrating a hardmask configuration, according to an embodiment of the invention.

FIG. 5 shows a cross-sectional view of the FIG. 4B structure following liner formation, according to an embodiment of the invention.

FIG. 6A shows a top-down view depicting an organic planarization layer (OPL) covering an n-type field-effect-transistor region, according to an embodiment of the invention.

FIG. 6B is a cross-sectional view of the structure in FIG. 5 taken along the line X1 in FIG. 6A following recessing of a semiconductor material, according to an embodiment of the invention.

FIG. 6C is a cross-sectional view taken along the line X2 in FIG. 6A and illustrating a configuration the OPL, according to an embodiment of the invention.

FIG. 7A shows a cross-sectional view of the FIG. 6B structure following formation of a p-type epitaxial layer, according to an embodiment of the invention.

FIG. 7B shows a cross-sectional view of the FIG. 6C structure following removal of the OPL, according to an embodiment of the invention.

FIG. 8A shows a top-down view depicting an OPL covering a p-type field-effect-transistor region, according to an embodiment of the invention.

FIG. 8B is a cross-sectional view taken along the line X1 in FIG. 8A and illustrating a configuration of the OPL, according to an embodiment of the invention.

FIG. 8C is a cross-sectional view taken along the line X2 in FIG. 6A, according to an embodiment of the invention.

FIG. 9A shows a cross-sectional view of the FIG. 8B structure following removal of the OPL and of a portion of the liner, according to an embodiment of the invention.

FIG. 9B shows a cross-sectional view of the FIG. 8C structure following removal of a portion of the liner and formation of an n-type epitaxial layer, according to an embodiment of the invention.

FIG. 10A shows a cross-sectional view of the FIG. 9A structure following removal of a remaining portion of the liner, according to an embodiment of the invention.

FIG. 10B shows a cross-sectional view of the FIG. 9B structure following removal of a remaining portion of the liner, according to an embodiment of the invention.

FIG. 11A shows a top-down view depicting formation of photoresists covering n-type and p-type field-effect-transistor regions to be used for fin cut patterning, according to an embodiment of the invention.

FIG. 11B is a cross-sectional view taken along the line Y in FIG. 11A showing a configuration of a photoresist and underlying mask layers and following formation of an n-type epitaxial layer on the structure of FIG. 4D, according to an embodiment of the invention.

FIG. 11C is a cross-sectional view taken along the line X2 in FIG. 11A showing a configuration of a photoresist and underlying mask layers on the structure of FIG. 10B, according to an embodiment of the invention.

FIG. 11D is a cross-sectional view taken along the line X3 in FIG. 11A and illustrating a configuration of mask layers in the dummy fin region, according to an embodiment of the invention.

FIG. 12A shows a cross-sectional view of the FIG. 11B structure following patterning of hardmask and OPL portions, according to an embodiment of the invention.

FIG. 12B shows a cross-sectional view of the FIG. 11C structure following removal of a photoresist, according to an embodiment of the invention.

FIG. 12C shows a cross-sectional view of the FIG. 11D structure following removal of a hardmask and part of an OPL of the mask region, according to an embodiment of the invention.

FIG. 13A shows a cross-sectional view of the FIG. 12A structure following patterning of an earlier formed hardmask, according to an embodiment of the invention.

FIG. 13B shows a cross-sectional view illustrating no change from the FIG. 12B structure following patterning of earlier formed hardmasks in connection with FIGS. 13A and 13C, according to an embodiment of the invention.

FIG. 13C shows a cross-sectional view of the FIG. 12C structure following removal of an earlier formed hardmasks, according to an embodiment of the invention.

FIG. 14A shows a top-down view depicting fin cut patterning by selective semiconductor layer removal, according to an embodiment of the invention.

FIG. 14B is a cross-sectional view taken along the line Y2 in FIG. 14A showing fin cut patterning by selective semiconductor layer removal from the structure of FIG. 13A, according to an embodiment of the invention.

FIG. 14C is a cross-sectional view taken along the line Y1 in FIG. 14A showing fin cut patterning by selective semiconductor layer removal, according to an embodiment of the invention.

FIG. 14D is a cross-sectional view taken along the line X2 in FIG. 14A showing removal of a hardmask layer and OPL from the structure of FIG. 13B, according to an embodiment of the invention.

FIG. 14E is a cross-sectional view taken along the line X3 in FIG. 14A showing fin cut patterning by selective semiconductor layer removal from the structure of FIG. 13C, according to an embodiment of the invention.

FIG. 15A shows a cross-sectional view of part of the FIG. 14D structure following formation of isolation regions, according to an embodiment of the invention.

FIG. 15B shows a cross-sectional view of part of the FIG. 14B structure following formation of isolation regions, according to an embodiment of the invention.

FIG. 16A shows a cross-sectional view of the FIG. 15A structure following formation of bottom spacers, according to an embodiment of the invention.

FIG. 16B shows a cross-sectional view of the FIG. 15B structure following formation of bottom spacers, according to an embodiment of the invention.

FIG. 17A shows a top-down view of a plurality of fins and a plurality of cut fin regions of a vertical transport field-effect transistor structure, according to an embodiment of the invention.

FIG. 17B is a cross-sectional view taken along the line Y2 in FIG. 17A showing the structure of FIG. 16B following gate structure, top source/drain epitaxial layer and contact formation, according to an embodiment of the invention.

FIG. 17C is a cross-sectional view taken along the line X2 in FIG. 17A showing the structure of FIG. 16A following gate structure, top source/drain epitaxial layer and contact formation, according to an embodiment of the invention.

FIG. 17D is a cross-sectional view taken along the line X4 in FIG. 17A showing contact formation on an epitaxial layer, according to an embodiment of the invention.

### DETAILED DESCRIPTION

Illustrative embodiments of the invention may be described herein in the context of illustrative methods for forming vertical transport field-effect transistor structures with straight fin cut profiles and varied contact distances to bottom source/drain regions, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Increasing demand for high density and performance in integrated circuit devices requires development of new structural and design features, including shrinking gate lengths and other reductions in size or scaling of devices. Continued scaling, however, is reaching limits of conventional fabrication techniques.

Vertical transport FETs (VTFETs) are being pursued as viable CMOS architectures for scaling to 7 nanometers (nm) and beyond. VTFETs provide the opportunity for further device scaling compared with other device architectures. VTFETs have various potential advantages over other conventional structures such as fin field-effect transistors (FinFETs). Such advantages may include improvements in density, performance, power consumption, and integration.

Illustrative embodiments provide techniques for forming vertical transport field-effect transistor structures with straight fin cut profiles and varied contact distances to bottom source/drain regions. As explained in more detail herein, in accordance with one or more embodiments, sacrificial silicon germanium (SiGe) material is used in a dummy fin region to enable selective removal with respect to a silicon (Si) fin during a fin cut last process. The selective removal of the sacrificial SiGe results in a straight fin cut profile. In addition, the techniques of the embodiments produce a vertical transport field-effect transistor structure with a bottom source/drain epitaxial layer having a periodic varying height, and a contact portion on the bottom source/drain epitaxial layer having the periodic varying height.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof shall relate to the disclosed structures and methods, as oriented in the drawing figures. For example, as used herein, “vertical” refers to a direction perpendicular to the top surface of the substrate in the cross-sectional views, and “horizontal” refers to a direction parallel to the top surface of the substrate in the cross-sectional views.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

FIG. 1 shows a top-down view of a plurality of fins Fₙ and Fₚ in respective n-type and p-type field-effect transistor (nFET and pFET) regions, and a plurality of cut fin regions C of a vertical transport field-effect transistor structure. FIG. 1 provides a non-limiting general overview of a configuration of fins in nFET and pFET regions, and spacing between the fins Fₙ and Fₚ in different directions. For example, in FIG. 1, the fins Fₙ and Fₚ are spaced apart the X-direction and, by virtue of a fin cut patterning process described herein, where portions the fins Fₙ and Fₚ are removed, the fins Fₙ and Fₚ are spaced apart in the Y-direction. Various cross-sections, including X1, X2 and Y are used to describe the embodiments. For ease of explanation, three fins are shown in each of the nFET and pFET regions. However, the embodiments are not necessarily limited thereto, and more or less than three fins may be used.

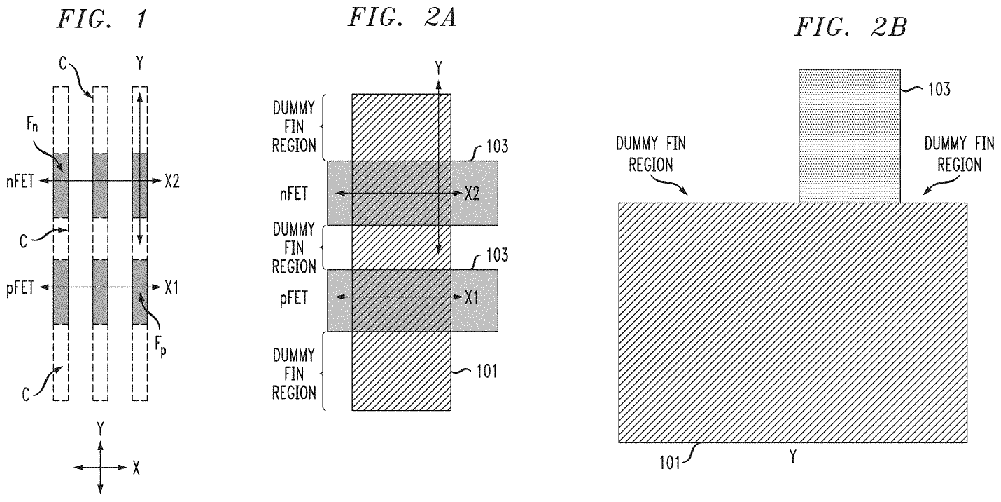

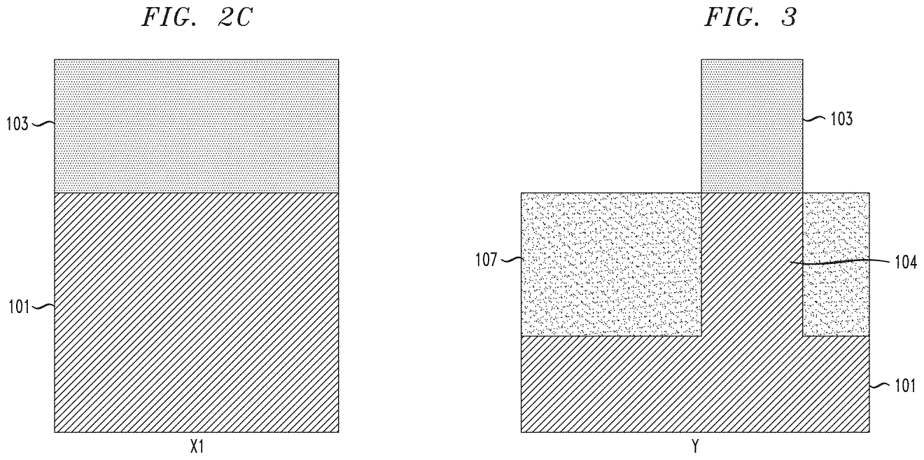

FIG. 2A shows a top-down view of formation of hardmasks 103 on a semiconductor substrate 101 covering nFET and pFET regions and exposing dummy fin regions, according to an embodiment of the invention. FIGS. 2B and 2C are cross-sectional views taken along the lines Y and X1, respectively in FIG. 2A and illustrating a configuration of the hardmasks 103. The hardmasks 103 are formed on the substrate 101 to cover nFET and pFET regions and expose dummy fin regions. A semiconductor substrate 101 comprises semiconductor material including, but not limited to, silicon (Si), silicon germanium (SiGe), III-V, II-V compound semiconductor or other like semiconductor. In addition, multiple layers of the semiconductor materials can be used as the semiconductor material of the substrate. In the embodiments described herein, the substrate 101 comprises silicon.

The hardmasks 103 can be formed by one or more of the deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD). The hardmask material can comprise for example, one or more dielectrics, including, but not necessarily limited to, silicon nitride (SiN), silicon carbide (SiC), silicon oxynitride (SiON), SiOC, silicon-carbon-nitride (SiCN), boron nitride (BN), silicon boron nitride (SiBN), silicoboron carbonitride (SiBCN), silicon-oxy-carbon-nitride (SiOCN), silicon oxide (SiOₓ) (where x is for example, 2, 1.99 or 2.01), and/or combinations thereof. The hardmasks 103, in some embodiments, may be formed as a multi-layer, such as a multi-layer of two layers including a nitride and oxide (e.g., SiN and silicon dioxide (SiO₂)), a multi-layer of three layers including one or more nitride and one or more oxide layers (e.g., SiN/SiO₂/SiN, SiO₂/SiN/SiO₂), etc.

FIG. 3, which is a cross-sectional view taken along the line Y in FIG. 2A, illustrates removal of portions of the substrate 101 in the dummy fin region left exposed by the hardmask 103. As shown in FIG. 3, semiconductor layers 107 are grown in the dummy fin regions in place of the removed portions of the substrate 101. In a fin patterning process, the remaining portion 104 of the substrate 101 under a bottom surface of the hardmask 103 and surrounded by the semiconductor layer 107 is patterned into a fin 105 used, for example, in a FET, such as a VTFET. Similarly, the semiconductor layer 107 is patterned into a dummy fin 107′ in a fin patterning process.

According to an embodiment, the semiconductor layers 107 comprise silicon germanium having a concentration of about 60% to about 80% germanium (e.g., SiGe 60% to about SiGe 80%). As explained further herein, the semiconductor layers 107 comprise a semiconductor material that can be selectively removed (e.g., by etching) with respect to a material of subsequently formed bottom source/drain regions, as well as with respect to a material of the substrate 101 and fins patterned from the substrate 101. In other embodiments, the material of the semiconductor layers 107 may vary depending on the material of the substrate 101 and of the bottom source/drain regions, as long as the etch selectivity of the material of the semiconductor layers 107 with respect to the materials of substrate 101 and bottom source/drain regions is preserved. In an embodiment, SiGe growth in a dummy region (e.g., semiconductor layers 107) enables selective SiGe removal with respect to silicon (e.g., material of substrate 101 and resulting fins 105) during a fin cut last process, which enables a straight fin profile.

As can be understood, the semiconductor layers 107 are epitaxially grown from their corresponding underlying semiconductor layers. Terms such as “epitaxial growth and/or deposition” and “epitaxially formed and/or grown” refer to the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on a semiconductor surface, and do not deposit material on dielectric surfaces, such as silicon dioxide or silicon nitride surfaces.

Examples of various epitaxial growth processes include, for example, rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for an epitaxial deposition process can range from 550° C. to 900° C. Although higher temperature typically results in faster deposition, the faster deposition may result in crystal defects and film cracking.

A number of different sources may be used for the epitaxial growth of the compressively strained layer. In some embodiments, a gas source for the deposition of epitaxial semiconductor material includes a silicon containing gas source, a germanium containing gas source, or a combination thereof. For example, an epitaxial silicon layer may be deposited from a silicon gas source including, but not necessarily limited to, silane, disilane, ldisilane, trisilane, tetrasilane, hexachlorodisilane, tetrachlorosilane, dichlorosilane, trichlorosilane, and combinations thereof. An epitaxial germanium layer can be deposited from a germanium gas source including, but not necessarily limited to, germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

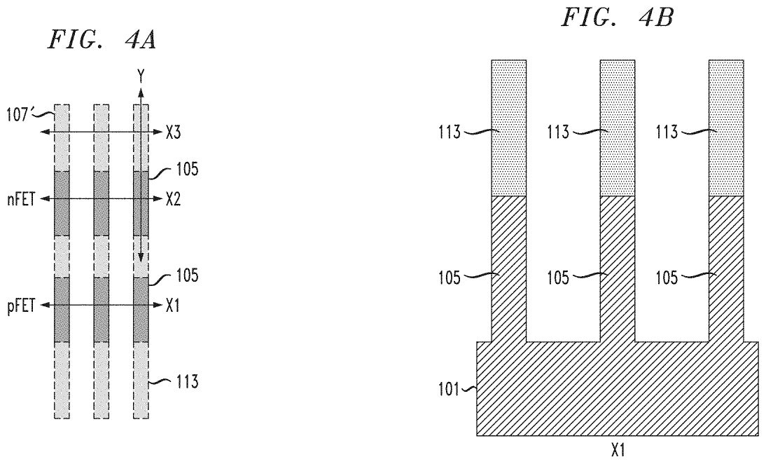

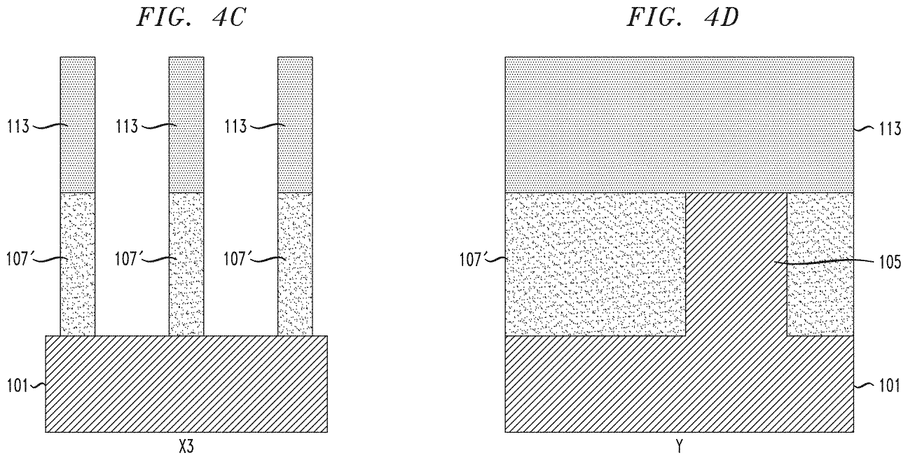

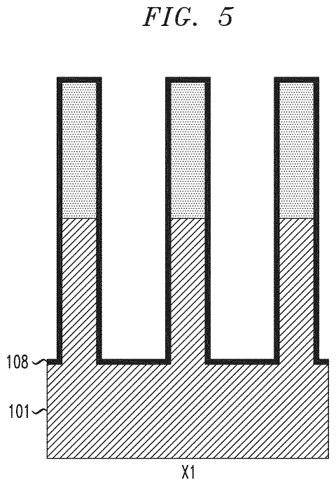

FIG. 4A shows a top-down view of formation of hardmasks 113 for fin patterning, according to an embodiment of the invention. Prior to formation of the hardmasks 113, the hardmasks 103 are stripped using, for example a wet strip process. The hardmasks 113 can be formed by one or more of the deposition techniques the same as or similar to those used to form the hardmasks 103, and can comprise the same or similar material as that used for the hardmasks 103. Similar to the hardmasks 103, in some embodiments, the hardmasks 113 may be formed as a multi-layer. As shown by the shaded portions in FIG. 4A, the hardmasks 113 are formed in a pattern over the dummy fin region and over the nFET and pFET regions to form a plurality of fins 105 and a plurality of dummy fins 107′ spaced apart from each other.

Referring also to the cross-sectional views in FIGS. 4B and 4C, the plurality of dummy fins 107′ are patterned from the deposited semiconductor layer 107 and the plurality of fins 105 are patterned from previously etched portions 104. The hardmasks 113 are formed over portions of the semiconductor layer 107 and etched portions 104 to be formed into the dummy fins 107′ and fins 105. The areas of the semiconductor layer 107 and etched portions 104 left exposed by the hardmasks 113 are etched to form the spacing between the dummy fins 107′ and between the fins 105. Referring to the cross-sectional view in FIG. 4D taken along the line Y in FIG. 4A, the hardmask 113 extends the entire length in the Y-direction over the resulting fins 105 and dummy fins 107′.

Fin patterning can be performed by any suitable patterning technique, including but not limited to, lithography (e.g., extreme ultraviolet (EUV)) in conjunction with reactive ion etching (RIE), self-aligned double patterning (SADP), self-aligned multiple patterning (SAMP), and/or self-aligned quadruple patterning (SAQP)). While embodiments of the present invention describe channel regions as fins, the embodiments are not necessarily limited to fin channel regions, and may include nanowire channel regions. Although the figures illustrate two or three fins 105 and dummy fins 107′ on the substrate 101, more or less than two or three fins 105 and dummy fins 107′ can be formed.

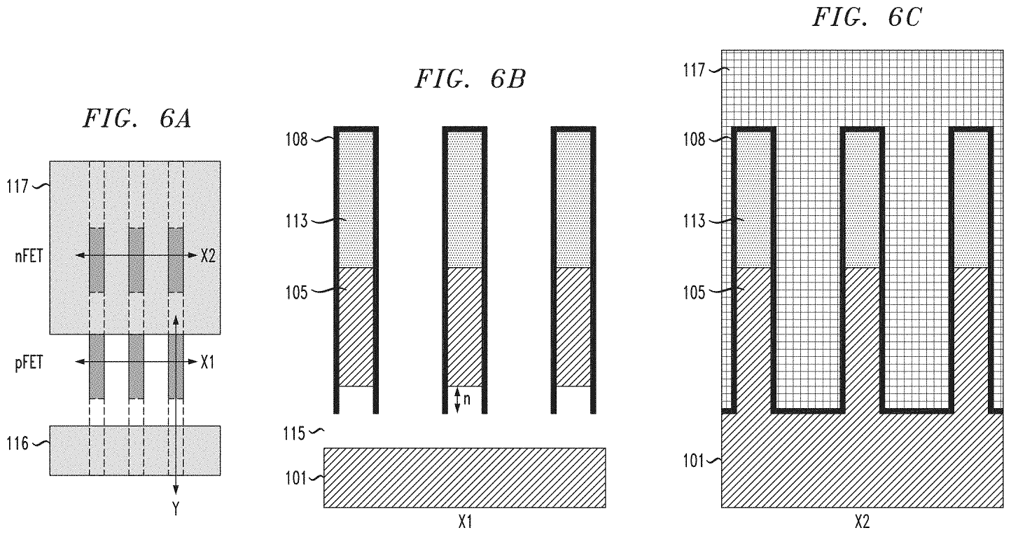

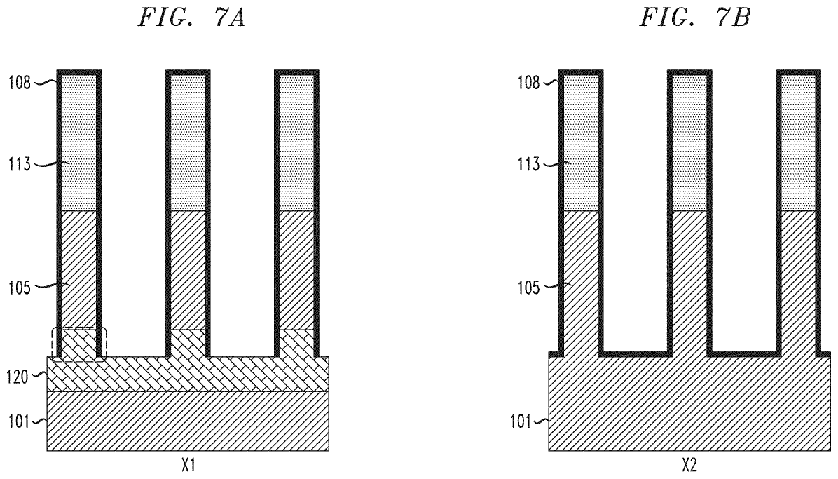

Referring to FIG. 5, which is a cross-sectional view of the FIG. 4B structure, a liner structure 108 is formed on the fins 105. According to an embodiment, the liner structure 108 can include oxide materials, nitride materials, and stacks of alternating layers of oxide materials and nitride materials. The layer or layers of the liner structure 108 are conformally deposited on the structure of FIG. 4B corresponding to the pFET region using a deposition technique such as, for example, ALD or CVD. As shown in FIG. 6C described in more detail herein, the liner structure 108 is similarly conformally formed on the substrate 101 and the fins 105 in the nFET region. Although not shown, a liner structure is also formed in the dummy fin region on the dummy fins 107′.

FIG. 6A shows a top-down view depicting an organic planarization layer (OPL) 116 covering a dummy fin region and an OPL 117 covering an nFET region and a dummy fin region. The OPLs 116 and 117 protect the dummy fin and nFET regions during patterning to form source/drain epitaxial layers under fins 105 in the pFET region, which is not covered by the OPLs 116 and 117. The OPLs 116 and 117 can be deposited, for example, by spin coating. The OPL material may be an organic polymer including C, H, and N. In an embodiment, the OPL material can be free of silicon (Si). According to an embodiment, the OPL material can be free of Si and fluorine (F). As defined herein, a material is free of an atomic element when the level of the atomic element in the material is at or below a trace level detectable with analytic methods available in the art.

As can be seen in FIG. 6C, which is a cross-sectional view taken along the line X2 in FIG. 6A, the OPL 117 is formed in the nFET region on the substrate 101 and around the fins 105 and hardmasks 113 including the liner structure thereon. FIG. 6B is a cross-sectional view taken along the line X1 in FIG. 6A. FIG. 6B illustrates the structure in FIG. 5 following recessing of portions of the fins 105 and the substrate 101 to form a vacant area 115 where a bottom source/drain epitaxial layer will be grown. According to an embodiment, horizontal portions of the liner structure are removed in a RIE process to expose the substrate 101 and etching of the substrate and lower portions of the fins 105 is performed to create the vacant area 115. A bottom level of the fins 105 depends on a recess time of the etching of the substrate 101 and fins 105. According to an embodiment, intentional over-etching is performed so that bottom surfaces of the fins 105 are above bottom surfaces of the liner structure (as shown by distance n). The etching of the substrate 101 and fins 105 comprises a RIE process using, for example, a fluorine-based material or a wet etch process. Although the fins 105 appear to be suspended in the cross-sectional view in FIG. 6B, the fins 105 extend and are supported on opposite sides of the vacant area 115 along the length of the fins 105 (going into or out of the page).

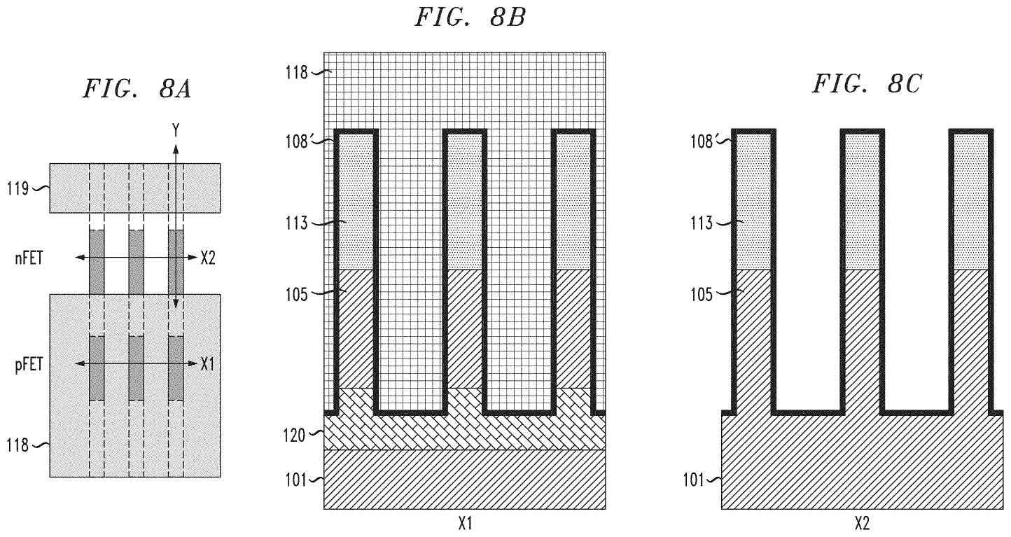

FIG. 7A shows a cross-sectional view of the FIG. 6B structure following formation of a p-type epitaxial source/drain layer 120. The growth of the epitaxial layer 120 is multi-directional in that the epitaxial layer 120 grows downward from the bottom surfaces of the fins 105 and upward from the upper surface of the substrate 101. The layers grown from the opposite surfaces meet or merge at a point between the bottom surfaces of the fins 105 and the upper surface of the substrate 101. Depending on growth time the shape of portions of the epitaxial layer 120 under the bottom surfaces of the fins 105 (see dotted line in FIG. 7A) may be rectangular as shown or trapezoidal. According to an embodiment, the material of the epitaxial layer 120 may comprise silicon germanium having a lower percentage of germanium than that of dummy fins 107′. For example, the epitaxial layer 120 may comprise SiGe 20%, SiGe 30% or other material or combination of materials such that the dummy fins 107′ can be selectively removed with respect to the epitaxial layer 120. In one or more embodiments, the p-type epitaxial layer 120 can be in-situ doped. Other alternative doping techniques can be used, including but not limited to, for example, ion implantation, gas phase doping, plasma doping, plasma immersion ion implantation, cluster doping, infusion doping, liquid phase doping, solid phase doping, etc., and dopants may include, for example, a p-type dopant selected from a group of B, Ga, In, and Tl at various concentrations. For example, in a non-limiting example, a dopant concentration range may be 1×10¹⁸/cm³ to 1×10²¹/cm³.

FIG. 7B shows a cross-sectional view of the FIG. 6C structure following removal of the OPL 117. The OPL 117 is removed prior to the growth of the epitaxial layer 120.

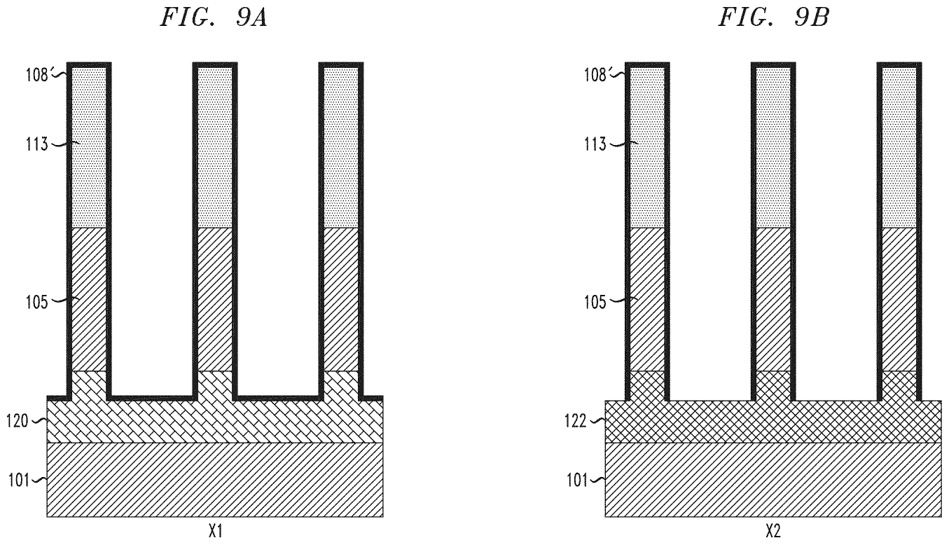

FIG. 8A shows a top-down view depicting an OPL 119 covering a dummy fin region and an OPL 118 covering a pFET region and a dummy fin region. The OPLs 119 and 118 protect the dummy fin and pFET regions during patterning to form source/drain epitaxial layers under fins 105 in the nFET region, which is not covered by the OPLs 119 and 118. Similar to the OPLs 116 and 117, the OPLS 118 and 119 can be deposited, for example, by spin coating, and may comprise the same or similar material as that of the OPLs 116 and 117.

As can be seen in FIG. 8B, which is a cross-sectional view taken along the line X1 in FIG. 8A, the OPL 118 is formed in the pFET region on the substrate 101 including the epitaxial layer 120 and around the fins 105 and hardmasks 113 including a liner structure thereon. Following formation of the epitaxial layer 120 as described in connection with FIG. 7A, part of or an entire portion of the liner structure 108 is stripped away by a wet etch process and a new liner structure 108′ is re-deposited such that a pristine liner structure is formed on both nFET and pFET regions. The new liner structure 108′ includes the same or similar materials and is formed using the same or similar processing as the previous liner structure 108. FIG. 8C is a cross-sectional view taken along the line X2 in FIG. 8A. FIG. 8B illustrates the new liner structure 108′.

Although not shown, similar to processing described in connection with FIG. 6B for the pFET region, portions of the fins 105 and the substrate 101 in the structure in FIG. 8C are recessed to form a vacant area where a bottom source/drain epitaxial layer will be grown. According to an embodiment, horizontal portions of the liner structure are removed in a RIE process to expose the substrate 101 and etching of the substrate and lower portions of the fins 105 is performed to create the vacant area. Similar to the structure in FIG. 6B, intentional over-etching is performed on the structure in FIG. 8C so that bottom surfaces of the fins 105 are above bottom surfaces of the liner structure.

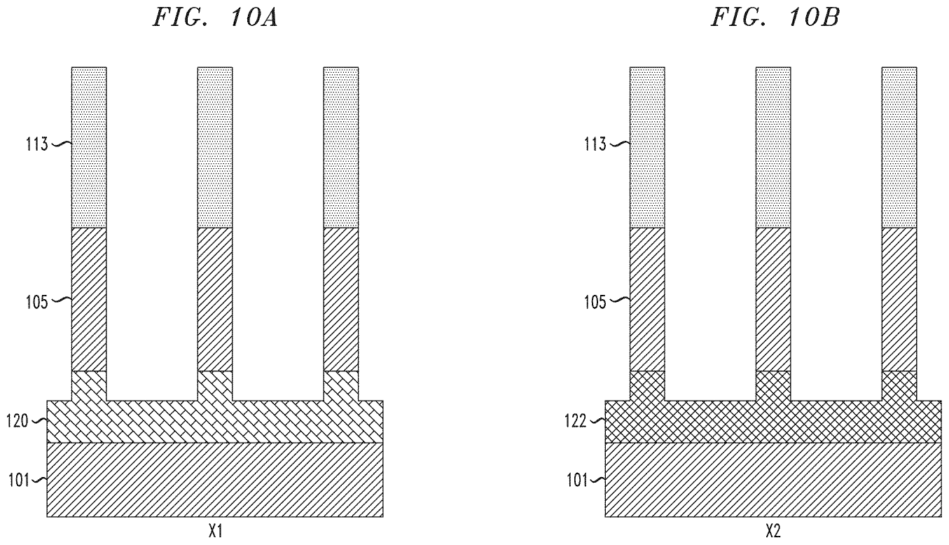

FIG. 9B shows a cross-sectional view of the FIG. 8C structure following formation of an n-type epitaxial source/drain layer 122. The growth of the epitaxial layer 122 is multi-directional in that the epitaxial layer 122 grows downward from the bottom surfaces of the fins 105 and upward from the upper surface of the substrate 101. The layers grown from the opposite surfaces meet or merge at a point between the bottom surfaces of the fins 105 and the upper surface of the substrate 101. Depending on growth time the shape of portions of the epitaxial layer 122 under the bottom surfaces of the fins 105 may be rectangular as shown or trapezoidal. According to an embodiment, the material of the epitaxial layer 122 may comprise silicon and a corresponding dopant. For example, the epitaxial layer 122 may comprise silicon doped with phosphorous (P) or other material or combination of materials such that the dummy fins 107′ can be selectively removed with respect to the epitaxial layer 122. The n-type epitaxial source/drain layer 122 can be in-situ doped. Other alternative doping techniques can be used, including but not limited to, for example, ion implantation, gas phase doping, plasma doping, plasma immersion ion implantation, cluster doping, infusion doping, liquid phase doping, solid phase doping, etc., and dopants may include, for example, an n-type dopant selected from a group of P, As and Sb. For example, in a non-limiting example, a dopant concentration range may be 1×10¹⁸/cm³ to 1×10²¹/cm³.

FIG. 9A shows a cross-sectional view of the FIG. 8B structure following removal of the OPL 118. The OPL 118 is removed prior to the growth of the epitaxial layer 122.

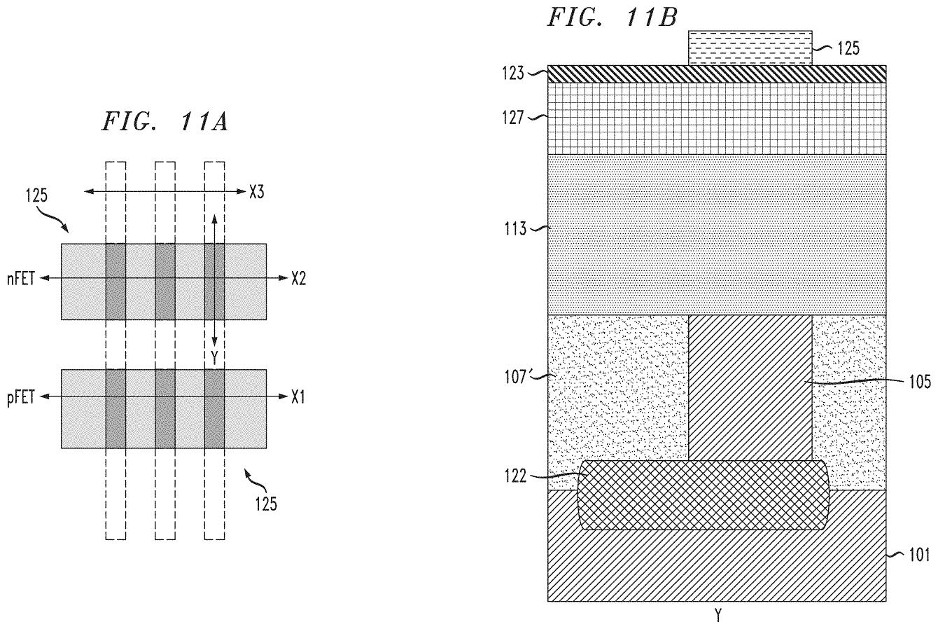

FIGS. 10A and 10B show cross-sectional views of the FIG. 9A structure and the FIG. 9B structure, respectively, following removal of the liner structure 108′. The liner structure 108′ in the nFET and pFET regions is stripped from fins 105, hardmasks 113 and epitaxial layers 120 and 122 of the structures of FIGS. 9A and 9B.

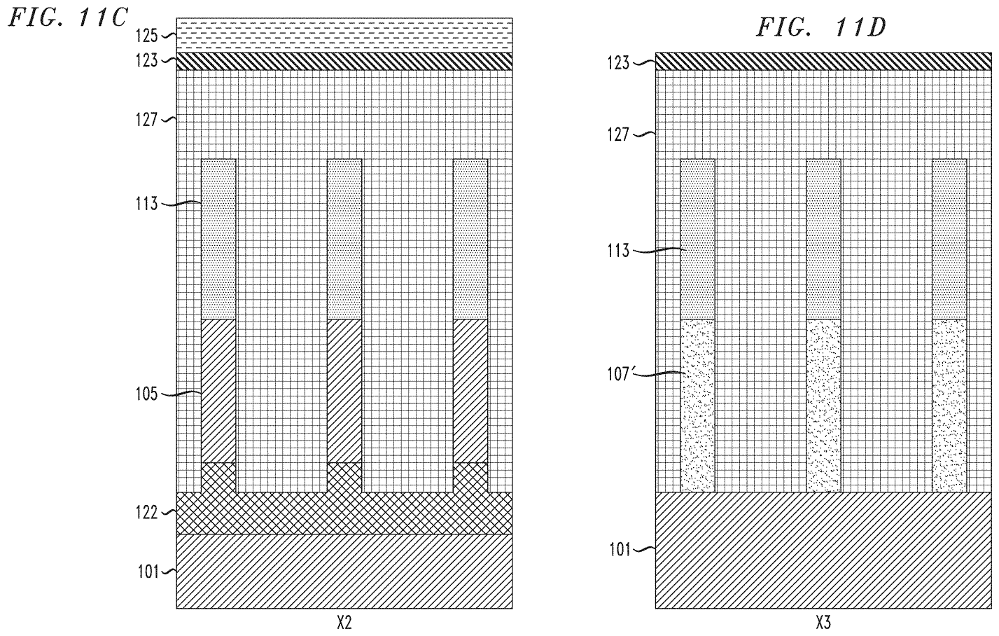

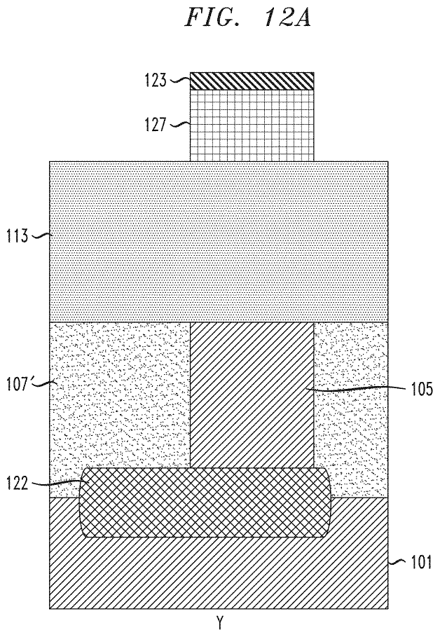

FIG. 11A shows a top-down view depicting formation of photoresists 125 covering n-type and p-type field-effect-transistor regions to be used for fin cut patterning, according to an embodiment of the invention. As shown in FIGS. 11B, 11C and 11D which are cross-sections taken along the lines Y, X2 and X3 in FIG. 1A, respectively, the photoresists 125 are not formed over the dummy fin regions. In more detail, OPLs 127 are formed on and around the hardmasks 113, the fins 105 and the epitaxial layers 120 or 122 in the pFET and nFET regions.

For example, FIG. 11C shows an OPL 127 on and around the hardmasks 113, the fins 105 and the epitaxial layer 122 in the nFET region. Referring to FIG. 11D, an OPL 127 is also formed on and around the hardmasks 113 and the dummy fins 107′ and on the substrate 101 in the dummy fin region. The cross-sectional view in FIG. 11B shows the OPL 127 top of a hardmask 113 and extending between dummy fin and nFET regions. FIG. 11B further illustrates a configuration of the bottom source/drain epitaxial layer 122 along a length of the fin 105, which also extends between dummy fin and nFET regions. Although not shown, the bottom source/drain epitaxial layer 120 extends between dummy fin and pFET regions along a length of a fin 105.

In each of FIGS. 11B-11D, a hardmask layer 123 is formed on the OPL 127. As shown in FIG. 11B, the photoresist 125 corresponds to the location of the fin 105 in the nFET region. Similarly, in FIG. 11C, the photoresist 125 covers the fins 105 in the nFET region. Although not shown, a photoresist covers fins 105 in the pFET region in the same manner as the fins 105 in the nFET region. As can be seen in FIG. 11D, there is no photoresist on the hardmask 123 in the dummy fin region. As explained in more detail herein, the correspondence of the photoresists 125 to the fins 105 is for protection during fin cut patterning, where the dummy fins 107′ are removed. Similar to the OPLs 116-119, the OPLs 127 can be deposited, for example, by spin coating, and may comprise the same or similar material as that of the OPLs 116-119. The hardmasks 123 can be formed by one or more of the deposition techniques the same as or similar to those used to form the hardmasks 103 and 113, and comprise a different material from that used for the hardmask 113. For example, the hardmask 113 comprises SiN or SiO₂, and the hardmask 123 comprises, for example, anti-reflective coating (ARC) or titanium oxide (TiO₂). Similar to the hardmasks 103 and 113, in some embodiments, the hardmasks 123 may be formed as a multi-layer.

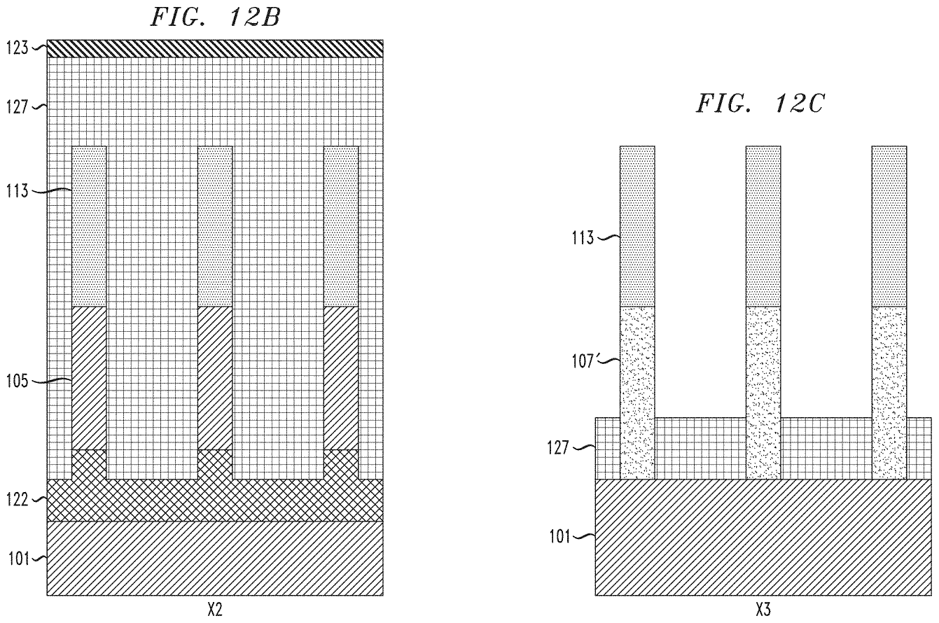

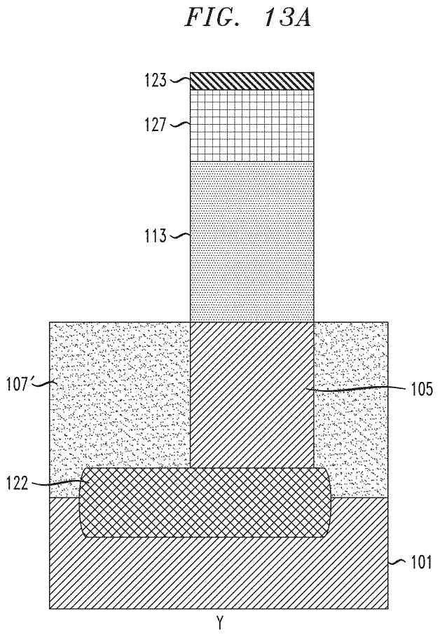

FIG. 12A shows a cross-sectional view of the FIG. 11B structure following patterning of a hardmask layer 123 and portions of an OPL 127, and simultaneous removal of the photoresist 125. As can be seen in FIG. 12A, the portions of the hardmask layer 123 and OPL 127 left exposed by the photoresist 125 are removed in, for example, a patterning process such as, for example, RIE. As a result of the patterning, portions of the hardmask 113 corresponding to the dummy fin region are exposed, and portions of the hardmask 113 corresponding to the nFET region are covered. Although not shown, a similar patterning process occurs with respect to the pFET region, where portions of the hardmask 113 corresponding to the dummy fin region are exposed, and portions of the hardmask 113 corresponding to the pFET region are covered by the remaining portions of the OPL and hardmask layers 127 and 123.

FIG. 12B shows a cross-sectional view of the FIG. 11C structure following removal of a photoresist 125. Since the photoresist 125 covered the entire hardmask layer 123 in FIG. 11C, there is no removal of the hardmask layer 123 or underlying OPL 127 in FIG. 12B, and only the photoresist 125 is removed during the hardmask and OPL patterning process. FIG. 12C shows a cross-sectional view of the FIG. 11D structure following removal of the hardmask layer 123 and part of the OPL 127. As there was no photoresist in the dummy fin region covering the structure in FIG. 11C, the hardmask layer 123 and a relatively large portion of the OPL layer 127 are removed from the FIG. 11C structure during the patterning process to result in the structure of FIG. 12C.

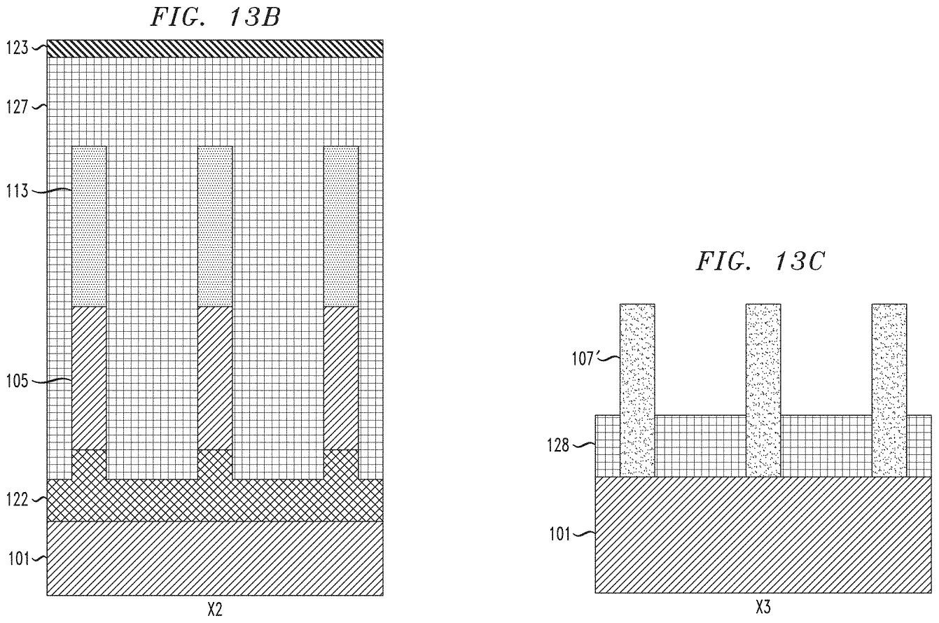

FIG. 13A shows a cross-sectional view of the FIG. 12A structure following patterning of the hardmask 113 left exposed after the previous removal of the portions of the hardmask layer 123 and OPL 127 discussed in connection with FIG. 12A. As shown in FIG. 13A, the portions of the hardmask layer 113 on the dummy fins 107′ are removed. The hardmask 123 may be partially, completely or not removed during etching of the hardmask layer 113, depending on a film thickness ratio between the hardmask layer 123 versus that of the hardmask layer 113, as well as chemistry used during the patterning process. In FIG. 13B, similar to what is noted above, hardmask 123 may be partially, completely or not removed during etching of the hardmask layer 113. If the hardmask layer 123 is not completely etched away during etching of the hardmask layer 113, after dummy fin removal, a wet etch process can be used to strip off the hardmask layer 123 along with OPL 128 in one wet etch step. Similar processing is performed in the pFET region. FIG. 13C shows a cross-sectional view of the FIG. 12C structure following removal of the hardmasks 113 in the dummy fin region. Since the hardmasks 113 were left exposed following the processing described in connection with FIG. 12C, the exposed hardmasks 113 are removed from the top of the dummy fins 107′. According to an embodiment, the process for removal of the exposed portions of the hardmasks 113 comprises a RIE process.

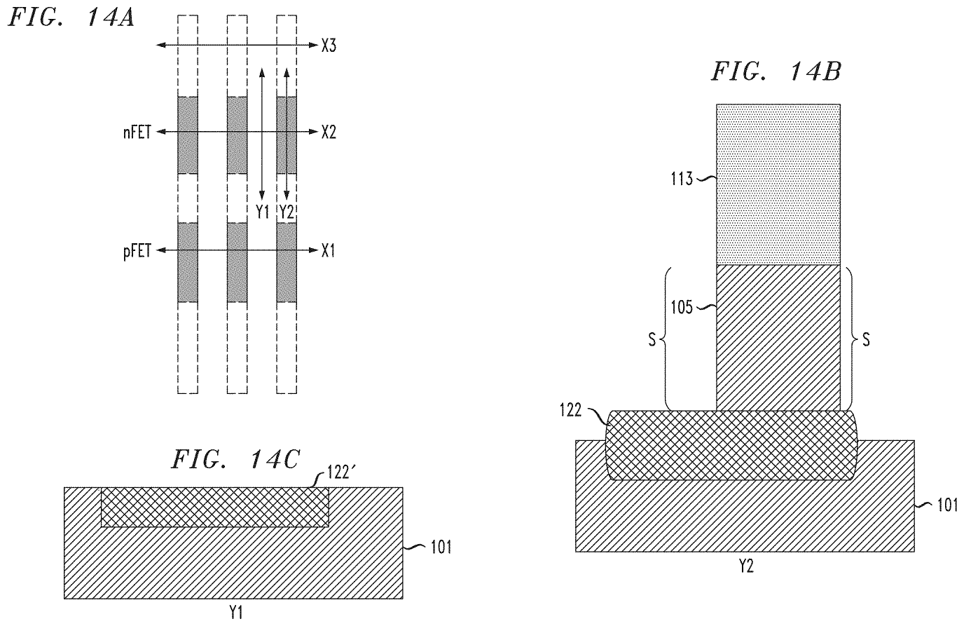

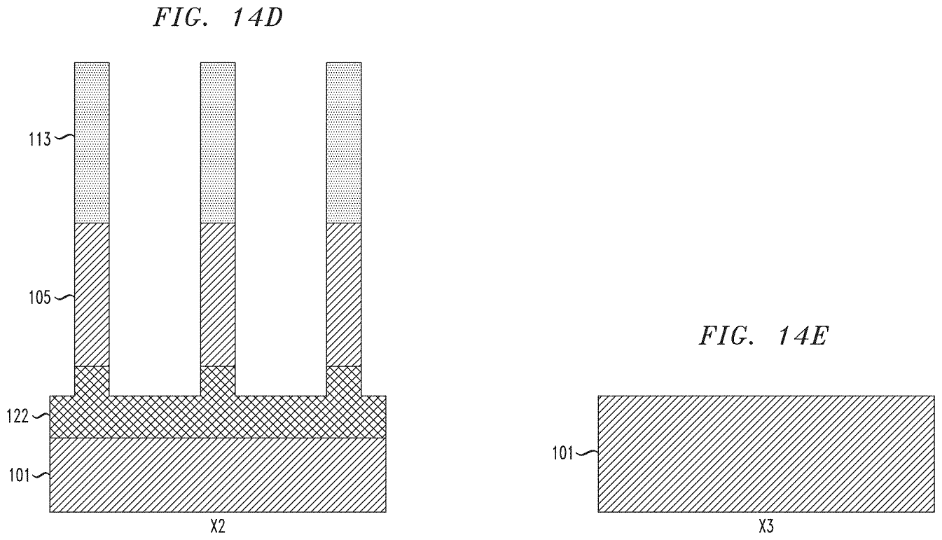

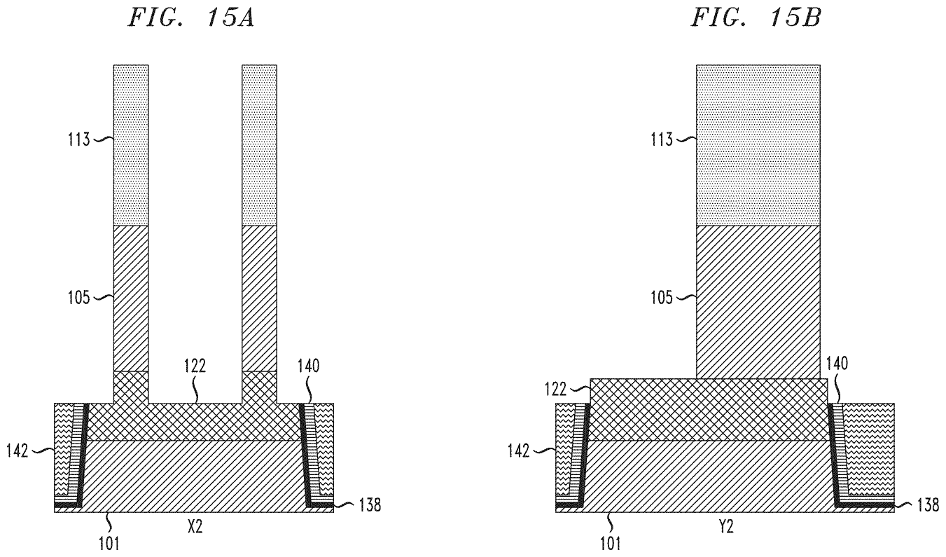

FIG. 14A shows a top-down view depicting fin cut patterning by selective semiconductor layer removal, according to an embodiment of the invention. In more detail, exposed dummy fins 107′ (located where the dotted portions in FIG. 14A are shown) are selectively removed from sides of adjacent fins 105 (shaded portions in FIG. 14A) in the nFET and pFET regions. Referring back to FIG. 3, the dummy fins 107′ were patterned from the earlier deposited semiconductor layer 107, which replaced the removed portions of the substrate 101 adjacent to a portion 104 from which the fins 105 were to be formed. This earlier removal of the portions of the substrate 101 was performed while the hardmask 103 was intact and not worn down from previous processing so that the sides of the portion 104 of the substrate eventually formed into the fin 105 by hardmask 113 have a straight profile corresponding to the sides of the overlying hardmask 103. The semiconductor layer 107 and subsequently formed dummy fins 107′ protect the sides of the fins adjacent the dummy fin region so that when the dummy fins 107′ are removed effectively completing the fin cut process, the cut or leading edge of the fin adjacent the dummy fin region has a straight profile (see portions S in FIG. 14B illustrating the straight profile).

FIG. 14B is a cross-sectional view taken along the line Y2 in FIG. 14A showing fin cut patterning by selective removal from the structure of FIG. 13A of the dummy fins 107′. As noted herein above, the material of the dummy fins 107′ comprises for example SiGe 60% to SiGe 80% or some other combination of silicon and germanium with a germanium concentration sufficient to permit selective material of the dummy fins 107′ with respect to the material of the fins 105 and the materials of the epitaxial layers 120 and 122. Depending on the materials of the fins 105 and epitaxial layers 120 and 122, the material of the dummy fins 107′ can be varied to include other semiconductor materials that can be selectively removed with respect to the materials of the fins 105 and epitaxial layers 120 and 122, and is not necessarily limited to SiGe or the noted percentages. The dummy fins 107′ are removed by a selective wet or dry etch processes such as, for example, a vapor phase HCl process. As can be seen in FIG. 14B, the remaining OPL 127 and hardmask 123 are removed following the removal of the dummy fins 107′. FIG. 14D is a cross-sectional view taken along the line X2 in FIG. 14A showing removal of the hardmask layer 123 and OPL 127 from the structure of FIG. 13B, according to an embodiment of the invention.

FIG. 14C is a cross-sectional view taken along the line Y1 in FIG. 14A an area including an epitaxial layer 122′ formed in the same or similar epitaxial growth process to that of the epitaxial layer 122 and having the same or similar materials to that of the epitaxial layer 122, but with no fin formation thereon. FIG. 14E is a cross-sectional view taken along the line X3 in FIG. 14A showing selective removal of the dummy fins 107′ and removal of the remaining OPL 127 from the structure of FIG. 13C, according to an embodiment of the invention.

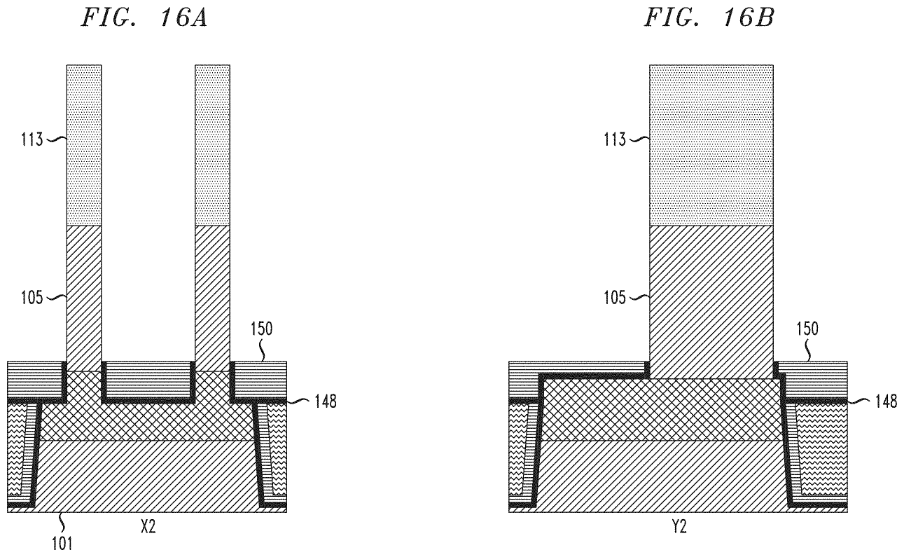

FIG. 15A shows a cross-sectional view of part of the FIG. 14D structure, and FIG. 15B shows a cross-sectional view of part of the FIG. 14B structure following formation of shallow trench isolation (STI) regions. Referring to FIGS. 15A and 15B, an STI region may comprise a multi-layer structure of isolation (e.g., dielectric) materials comprising, for example, first, second and third dielectric layers 138, 140 and 142 comprising, for example, multiple oxide layer, multiple nitride layers or combinations thereof. Alternatively, the STI region may comprise a single layer of isolation material. The dielectric materials for the STI region include, but are not limited to SiO₂, low-temperature oxide (LTO), high-temperature oxide (HTO), field oxide (FOX) or some other dielectric or combination of dielectrics, which is deposited on the structures from FIGS. 14B and 14D, and recessed to form the STI region. As can be seen in FIGS. 15A and 15B, STI regions comprising dielectric layers 138, 140 and 142 are formed surrounding the epitaxial layer 122 (e.g., bottom source/drain region) to provide device isolation. Although not shown, similar STI regions are formed in the pFET region around the epitaxial layer 120 (e.g., bottom source/drain region) to provide device isolation.

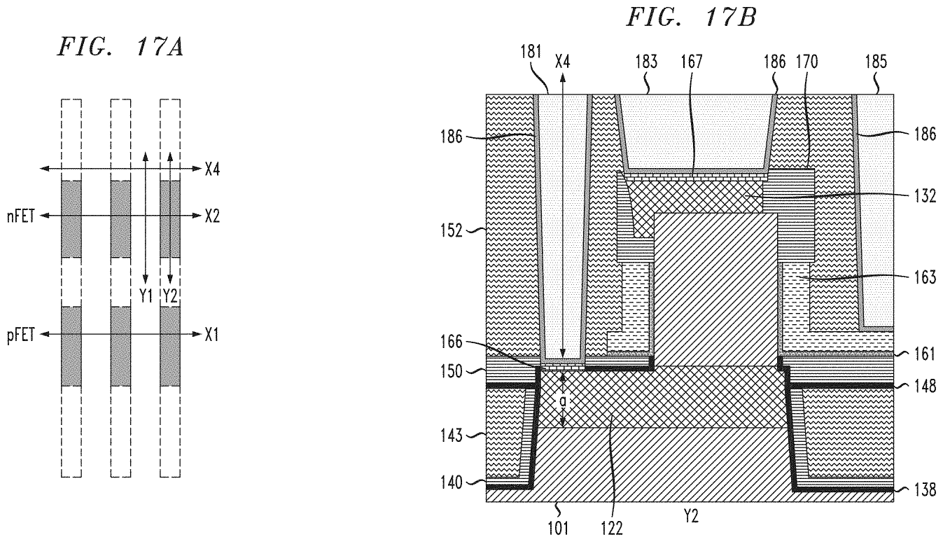

FIG. 16A shows a cross-sectional view of the FIG. 15A structure, and FIG. 16B shows a cross-sectional view of the FIG. 15B structure following formation of bottom spacers. FIGS. 16A and 16B show bottom spacers having multiple dielectric layers 148 and 150. Alternatively, the bottom spacers may each comprise a single dielectric layer. The bottom spacers are formed on the STI regions and on the epitaxial layer 122. The bottom spacers surround part of the epitaxial layer 122 and part of the bottom portions the vertical fins 105 above the epitaxial layer 122 and STI regions. The bottom spacers are disposed on portions of the epitaxial layer 122 between two vertical fins 105 and also between portions of the epitaxial layer 122 that are not under the fins 105, but were previously under dummy fins 107′. The bottom spacers may be formed using various processing, such as non-conformal deposition and etch-back processing (e.g., PVD, high density plasma (HDP) deposition, etc.). The bottom spacers may be formed of a dielectric material such as SiO₂, SiN, silicon carbide oxide (SiCO), SiBCN, etc. or combinations thereof. Although not shown, similar bottom spacers are formed in the pFET region on STI regions, on the epitaxial layer 120, and surrounding part of the epitaxial layer 120 and part of the bottom portions the vertical fins 105 above the epitaxial layer 120 and STI regions.

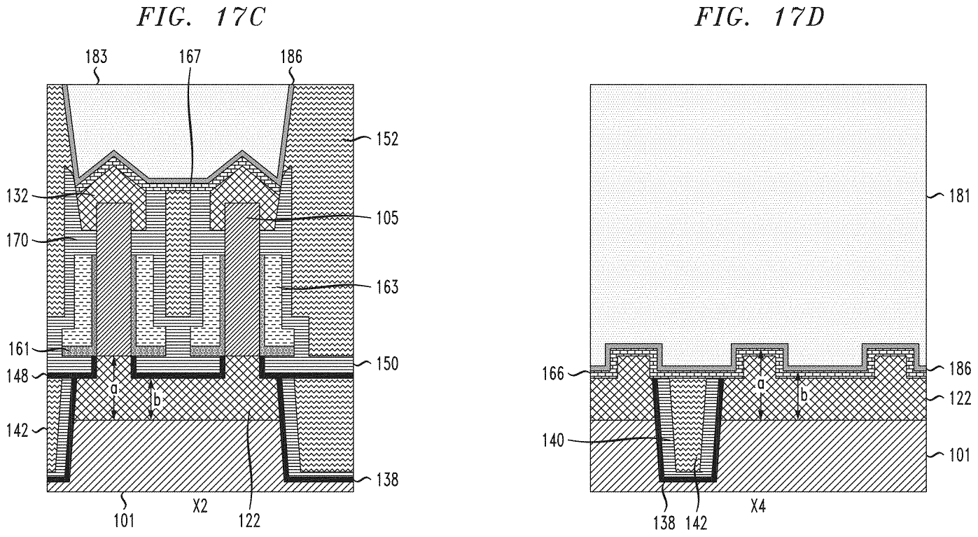

FIG. 17A shows a top-down view of a plurality of fins and a plurality of fin cut regions of a vertical transport field-effect transistor structure. In more detail, the fin cut regions correspond to the dotted portions where the dummy fins 107′ were selectively removed from sides of adjacent fins 105 (shaded portions) in the nFET and pFET regions.

FIG. 17B is a cross-sectional view taken along the line Y2 in FIG. 17A, and FIG. 17C is a cross-sectional view taken along the line X2 in FIG. 17A. FIGS. 17B and 17C show the structures of FIGS. 16B and 16A, respectively following gate structure, top source/drain epitaxial layer and contact formation. Referring to FIGS. 17B and 17C, gate layers 163 are formed on high-k dielectric layers 161. The high-k dielectric layers 161 include, for example, a high-k material including, but not necessarily limited to, HfO₂ (hafnium oxide), ZrO₂ (zirconium dioxide), hafnium zirconium oxide Al₂O₃ (aluminum oxide), and Ta₂O₅ (tantalum pentoxide). The high-k dielectric layers 161 are conformally deposited on the bottom spacers including layers 150 and 148, and on the fins 105.

The gate layers 163 may each include a work-function metal (WFM) layer deposited on the high-k dielectric layer 161. The WFM layer includes, for example, titanium nitride (TiN), tantalum nitride (TaN), ruthenium (Ru), titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN or TaN.

The gate layers 163 further include a gate metal layer deposited on the WFM layer. The gate metal layer includes, for example, a low resistance metal, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof.

The gate layers 163 including the gate metal and WFM layers, and the high-k gate dielectric layer 161 are deposited using, for example, deposition techniques including, but not limited to, CVD, PECVD, RFCVD, PVD, ALD, MBD, PLD, LSMCD, sputtering, and/or plating. An isotropic etch is performed to recess the gate structures, including the gate and high-k gate dielectric layers 163 and 161. As can be seen, the gate and high-k dielectric layers 163 and 161 are formed in L-shapes on sides of the fin 105 and on top of the bottom spacer including the layers 148 and 150.

Upper epitaxial layers 132 (also referred to herein as “top source/drain regions”) are epitaxially grown in epitaxial growth processes from the upper portions of the fins 105. The epitaxially grown top source/drain regions 132 can be in-situ doped. Other alternative doping techniques can be used, including but not limited to, for example, ion implantation, gas phase doping, plasma doping, plasma immersion ion implantation, cluster doping, infusion doping, liquid phase doping, solid phase doping, etc., and dopants may include, for example, an n-type dopant selected from a group of P, As and Sb, and a p-type dopant selected from a group of B, Ga, In, and Tl at various concentrations. For example, in a non-limiting example, a dopant concentration range may be 1×11¹⁸/cm³ to 1×10²¹/cm³.

Top spacer layers 170 are formed on the recessed gate structures including the gate and high-k gate dielectric layers 163 and 161, and on and around the fins 105 and upper epitaxial layers 132. The top spacer layers 170 include, for example, SiN, SiBN, SiBCN, SiOCN or other dielectric. According to an embodiment of the present invention, the top spacer layer 170 is conformally deposited using, for example, deposition techniques including, but not limited to, CVD, PECVD, RFCVD, PVD, ALD, MBD, PLD, LSMCD, sputtering, and/or plating.

A dielectric material, including, but not limited to SiOₓ, low temperature oxide (LTO), high temperature oxide (HTO), field oxide (FOX) or some other dielectric, is deposited to form an inter-layer dielectric (ILD) layer 152 on the recessed gate structures, including the top spacers 170 thereon, and over the top source/drain regions 132 and to fill in gaps between the top source/drain regions 132. The ILD layer 152 can be deposited using deposition techniques including, but not limited to, CVD, PECVD, RFCVD, PVD, ALD, MBD, PLD, and/or LSMCD, sputtering, and/or plating. Planarization, for example, chemical mechanical polishing (CMP) can be performed to remove excess material from layer 152 and planarize the resulting structure. In accordance with an embodiment of the present invention, the ILD layer 152 electrically isolates different vertical transport field-effect transistors and contact regions from each other.

Trenches are respectively opened in the ILD layer 152 over and to the top source/drain regions 132, over and to the bottom source/drain region 122 and over and to the gate layer 163. The trenches are opened using, for example, lithography followed by RIE. Contacts to the bottom source/drain region 122, top source/drain regions 132 and the gate layer 163 are formed in the trenches by filling the trenches with contact material layers 181, 183 and 185, respectively. The contact material layers 181, 183 and 185 comprise, for example, electrically conductive material including, but not necessarily limited to, tungsten, cobalt, zirconium, tantalum, titanium, aluminum, ruthenium, and/or copper. A liner layer 186 including, for example, titanium and/or titanium nitride, may be formed on the bottom source/drain region 122, top source/drain regions 132 and the gate layer 163 and on side and bottom surfaces of the trenches before filling the trenches with the contact material layers 181, 183 and 185. The liner layer 186 can be omitted.

A silicide layer 166, 167 may optionally be formed on the portions of the source/drain regions 122 and 132 by, for example, silicidation (e.g., formation of an alloy including a portion of a contact material with silicon in an underlying semiconductor layer) before filling the trenches over the source/drain regions 122 and 132 with a remainder of electrically conductive material and liner layers (if used). More specifically, a metal layer including a material capable of forming a silicide is deposited on the exposed portions of the layers 122 and 132 (or 120) after trench formation. The material can include, but is not necessarily limited to, metals such as cobalt, nickel, platinum, titanium, tantalum and tungsten, or combinations thereof. The material preferably is thermally stable, being able to remain stable under high temperatures due to subsequent steps performed under high temperature conditions.

A process, such as, for example, an annealing process at approximately 300° C. to approximately 450° C., is performed so that the metal layer reacts with silicon in the layers 122 and 132 (or 120) to convert a portion of the layers 122 and 132 (or 120) into silicide layers 166 and 167. The annealing process is not necessarily limited to the temperature range above, and may be performed at other temperatures if required. The silicide layers 166 and 167 may include, but are not necessarily limited to, cobalt silicide (CoSiₓ), tungsten silicide (WSiₓ), nickel silicide (NiSi), nickel platinum silicide (NiPt_{y}Siₓ), tantalum silicide (TaSiₓ), titanium silicide (TiSiₓ) and combinations thereof. Following silicidation, liner layers 186 (if used) and/or the remainder of the contact material layers 181, 183 and 185 are deposited to fill in the trenches. Deposition of the contact material layers 181, 183 and 185 can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP.

FIG. 17D is a cross-sectional view taken along the lines X4 in FIG. 17A and in FIG. 17B. Referring to FIGS. 17B, 17C and 17D, the epitaxial layer 122 (e.g., bottom source/drain region) comprises a plurality of different heights a and b. As shown in FIG. 17D, the heights a and b can include the portions of the epitaxial layer 122 converted to silicide portions 166 if silicidation is performed. Alternatively, if silicidation is not performed the contact material layer 181 and liner layer 186 are formed directly on the epitaxial layer 122. As noted herein above, the liner layer 186 can be omitted.

A contact material layer 181 is disposed on the epitaxial layer 122 on respective surfaces of the epitaxial layer at the plurality of different heights. The height a, which is greater than the height b corresponds to a height of a portion of the epitaxial layer 122 disposed under a bottom surface of at least one vertical fin 105. A width of the portion of the epitaxial layer 122 disposed under the bottom surface of the at least one vertical fin is the same or substantially the same as a width of the at least one vertical fin 105. The height b corresponds to a height of a portion of the epitaxial layer 122 disposed between two fins 105. The heights a and b are arranged in a repetitive pattern comprising the first height followed by the second height along a given direction of the epitaxial layer 122. The pattern can start with either height a or height b. As shown in FIG. 17D, an isolation region including, for example, layers 138, 140 and 142 can separate portions of the epitaxial layer 122 and have a height corresponding to the smaller dimension (e.g., height b). It is to be understood that the same or similar processing to that used in the nFET region is used to form gate structures, top source/drain epitaxial layers and contacts in the pFET region comprising the epitaxial layers 120.

It is to be appreciated that the various materials, processing methods (e.g., etch types, deposition types, etc.) and dimensions provided in the discussion above are presented by way of example only. Various other suitable materials, processing methods, and dimensions may be used as desired.

Semiconductor devices and methods for forming same in accordance with the above-described techniques can be employed in various applications, hardware, and/or electronic systems. Suitable hardware and systems for implementing embodiments of the invention may include, but are not limited to, sensors and sensing devices, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
at least one vertical fin;
an epitaxial layer adjacent a bottom portion of the at least one vertical fin, wherein the epitaxial layer comprises a plurality of different heights; and
a contact structure disposed on the epitaxial layer, wherein the contact structure is disposed on respective surfaces of the epitaxial layer at the plurality of different heights.

2. The semiconductor structure of claim 1, wherein the epitaxial layer comprises a bottom source/drain region of at least one vertical transport field-effect transistor.

3. The semiconductor structure of claim 2, further comprising an additional epitaxial layer disposed on a top portion of the at least one vertical fin, wherein the additional epitaxial layer comprises a top source/drain region of the at least one vertical transport field-effect transistor.

4. The semiconductor structure of claim 3, further comprising a gate structure formed on one or more sides of the at least one vertical fin and disposed between the bottom and top source/drain regions.

5. The semiconductor structure of claim 1, wherein:
the plurality of different heights comprise a first height and a second height greater than the first height; and
the second height corresponds to a portion of the epitaxial layer disposed under a bottom surface of the at least one vertical fin.

6. The semiconductor structure of claim 5, wherein a width of the portion of the epitaxial layer disposed under the bottom surface of the at least one vertical fin is the same or substantially the same as a width of the at least one vertical fin.

7. The semiconductor structure of claim 5, wherein the first height corresponds to a portion of the epitaxial layer disposed between the at least one vertical fin and at least one other vertical fin.

8. The semiconductor structure of claim 7, further comprising a spacer layer disposed on the portion of the epitaxial layer between the at least one vertical fin and the at least one other vertical fin.

9. The semiconductor structure of claim 1, wherein:
the plurality of different heights comprise a first height and a second height greater than the first height; and
wherein the first height and the second height are arranged in a repetitive pattern comprising the first height followed by the second height along a given direction of the epitaxial layer.

10. A vertical transport field-effect transistor structure, comprising:
at least one vertical channel region;
a bottom source/drain region adjacent a bottom portion of the at least one vertical channel region, wherein the bottom source/drain region comprises a plurality of different heights;
a top source/drain region disposed on a top portion of the at least one vertical channel region; and
a contact structure disposed on the bottom source/drain region, wherein the contact structure is disposed on respective surfaces of the bottom source/drain region at the plurality of different heights.

11. The vertical transport field-effect transistor structure of claim 10, wherein:
the plurality of different heights comprise a first height and a second height greater than the first height; and
wherein the first height and the second height are arranged in a repetitive pattern comprising the first height followed by the second height along a given direction of the bottom source/drain region.

12. The vertical transport field-effect transistor structure of claim 10, wherein:
the plurality of different heights comprise a first height and a second height greater than the first height; and
the second height corresponds to a portion of the bottom source/drain region disposed under a bottom surface of the at least one vertical channel region.

13. The vertical transport field-effect transistor structure of claim 12, wherein the first height corresponds to a portion of the bottom source/drain region disposed between the at least one vertical channel region and at least one other vertical channel region.

14. The semiconductor structure of claim 13, further comprising a spacer layer disposed on the portion of the bottom source/drain region between the at least one vertical channel region and the at least one other vertical channel region.

15. A method of forming a semiconductor structure, comprising:
forming a mask on a first portion of a semiconductor substrate, wherein the first portion corresponds to a transistor region;
removing part of a second portion of the semiconductor substrate left exposed by the mask, wherein the second portion corresponds to a dummy region;
growing a sacrificial semiconductor layer in the dummy region in place of the removed part of the second portion;
forming at least one vertical fin in the transistor region;
forming an epitaxial layer adjacent a bottom portion of the at least one vertical fin; and
selectively removing the sacrificial semiconductor layer with respect to the epitaxial layer.

16. The method of claim 15, wherein:
the sacrificial semiconductor layer comprises silicon germanium; and
the epitaxial layer comprises silicon germanium with a lower percentage of germanium than the sacrificial semiconductor layer.

17. The method of claim 15, wherein the sacrificial semiconductor layer is formed on one or more sides of the at least one vertical fin.

18. The method of claim 15, wherein:
the epitaxial layer comprises a plurality of different heights; and
the method further comprises forming a contact structure on the epitaxial layer, wherein the contact structure is disposed on respective surfaces of the epitaxial layer at the plurality of different heights.

19. The method of claim 15, wherein:
the epitaxial layer comprises a plurality of different heights;
the plurality of different heights comprise a first height and a second height greater than the first height; and
the first height and the second height are arranged in a repetitive pattern comprising the first height followed by the second height along a given direction of the epitaxial layer.

20. The method of claim 15, wherein:
the epitaxial layer comprises a plurality of different heights;
the plurality of different heights comprise a first height and a second height greater than the first height; and
the second height corresponds to a portion of the epitaxial layer disposed under a bottom surface of the at least one vertical fin.
